(19) United States
(12) Patent Application Publication
(10) Pub. No.: US 2023/0049663 A1
(43) Pub. Date: Feb. 16, 2023

(54) ADDRESS CONTROL CIRCUIT AND SEMICONDUCTOR APPARATUS INCLUDING THE SAME

(71) Applicant: SK hynix Inc., Icheon-si Gyeonggi-do (KR)

(72) Inventors: Ji Eun KIM, Icheon-si Gyeonggi-do (KR); Min Wook OH, Icheon-si Gyeonggi-do (KR)

(73) Assignee: SK hynix Inc., Icheon-si Gyeonggi-do (KR)

(21) Appl. No.: 17/670,892

(22) Filed: Feb. 14, 2022

(30) Foreign Application Priority Data
Aug. 10, 2021 (KR) 10-2021-0105520

(51) Int. Cl. G11C 7/10; G11C 8/06

(52) U.S. Cl. CPC G11C 7/1039; G11C 7/1012; G11C 7/1063; G11C 7/109; G11C 8/06

(57) ABSTRACT

An address control circuit includes an address timing control circuit configured to latch address signals inputted from outside the address timing control circuit, sequentially store the latched signals at predetermined timings, and output the stored signals as a bank group address. The address control circuit also includes an address multiplexing circuit configured to generate bank group select signals according to the bank group address. The address multiplexing circuit is configured to generate the bank group select signals having a second value according to the bank group address having a first value when a preset memory access mode is a first memory access mode, and generate the bank group select signals having the second value according to the bank group address having a third value different from the first value when the preset memory access mode is a second memory access mode.

### CROSS-REFERENCE TO RELATED APPLICATION

The present application claims priority under 35 U.S.C. § 119(a) to Korean application number 10-2021-0105520, filed on Aug. 10, 2021, in the Korean Intellectual Property Office, which is incorporated herein by reference in its entirety.

### BACKGROUND

### 1. Technical Field

Various embodiments generally relate to a semiconductor circuit, and particularly, to an address control circuit and a semiconductor apparatus including the same.

### 2. Related Art

A semiconductor apparatus, e.g. a semiconductor memory apparatus, has a variety of criteria for determining the performance thereof, and one of the criteria is current consumption. There are various operation standards for determining the current consumption characteristic of a semiconductor memory apparatus. Therefore, it is very important to design the semiconductor memory apparatus capable of satisfying the above-described operation standards. In particular, the physical arrangement of memory areas of the semiconductor memory apparatus needs to be designed to have advantages in terms of the operation standards.

### SUMMARY

Various embodiments are directed to an address control circuit capable of reducing an operation current, and a semiconductor apparatus including the same.

In an embodiment, an address control circuit may include: an address timing control circuit configured to latch address signals inputted from outside the address timing control circuit, sequentially store the latched signals at predetermined timings, and output the stored signals as a bank group address; and an address multiplexing circuit configured to generate bank group select signals according to the bank group address. The address multiplexing circuit may be configured to generate the bank group select signals having a second value according to the bank group address having a first value when a preset memory access mode is a first memory access mode, and generate the bank group select signals having the second value according to the bank group address having a third value different from the first value when the preset memory access mode is a second memory access mode.

The address multiplexing circuit may include: an address multiplexer configured to generate some pre-decoding signals according to a first address bit of the bank group address and generate the others of the pre-decoding signals according to a second address bit of the bank group address, when the memory access mode is the first memory access mode, and generate some of the pre-decoding signals according to the second address bit of the bank group address and generate the others of the pre-decoding signals according to the first address bit of the bank group address, when the memory access mode is the second memory access mode; and a decoding circuit configured to output signals, obtained by decoding the pre-decoding signals, as the bank group select signals.

In an embodiment, a semiconductor apparatus may include: a memory area comprising a plurality of memory banks divided into a plurality of bank groups; and an address control circuit configured to generate bank group select signals according to a bank group address. The address control circuit may be configured to generate the bank group select signals having a second value according to the bank group address having a first value when a preset memory access mode is a first memory access mode, and generate the bank group select signals having the second value according to the bank group address having a third value different from the first value when the preset memory access mode is a second memory access mode, and selectively operate the plurality of bank groups when the memory access mode is the first memory access mode, and pair the plurality of memory banks and selectively operate the paired memory banks when the memory access mode is the second memory access mode.

The address control circuit may include: an address multiplexer configured to generate some pre-decoding signals according to a first address bit of the bank group address and generate the others of the pre-decoding signals according to a second address bit of the bank group address, when the memory access mode is the first memory access mode, and generate some of the pre-decoding signals according to the second address bit of the bank group address and generate the others of the pre-decoding signals according to the first address bit of the bank group address, when the memory access mode is the second memory access mode; and a decoding circuit configured to output signals, obtained by decoding the pre-decoding signals, as the bank group select signals.

In an embodiment, a semiconductor apparatus may include: a memory area comprising a plurality of memory banks divided into a plurality of bank groups; and an address control circuit configured to generate bank group select signals for selecting any one bank group among the plurality of bank groups according to a bank group address. The address control circuit may be configured to change values of the bank group select signals in order to match two bank groups selected in a first memory access mode with two bank groups selected in a second memory access mode, during consecutive read operations on two different memory banks among the plurality of memory banks.

### BRIEF DESCRIPTION OF THE DRAWINGS

FIG. 1 is a diagram illustrating a configuration of a semiconductor apparatus in accordance with an embodiment.

FIGS. 2A and 2B are diagrams illustrating an example of a bank group mode operation in accordance with an embodiment.

FIGS. 3A and 3B are diagrams illustrating an example of an 8-bank mode operation in accordance with an embodiment.

FIG. 4 is a diagram illustrating a configuration of an address control circuit in accordance with an embodiment.

FIG. 5 is a diagram illustrating a configuration of an address multiplexing circuit in accordance with an embodiment.

### DETAILED DESCRIPTION

Hereafter, some embodiments will be described in more detail with reference to the accompanying drawings.

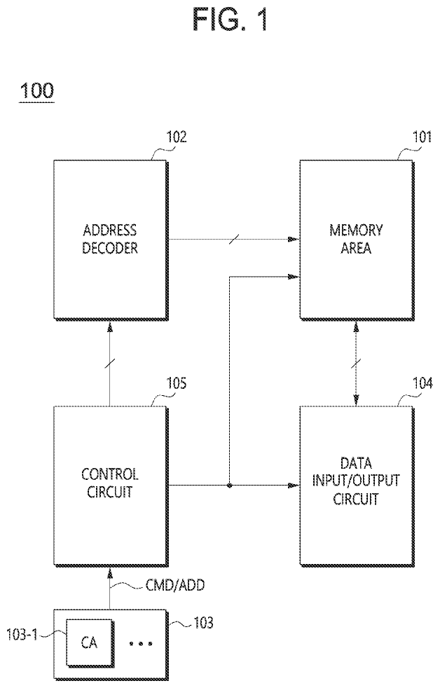

FIG. 1 is a diagram illustrating a configuration of a semiconductor apparatus 100 in accordance with an embodiment.

Referring to FIG. 1, the semiconductor apparatus 100 may include a memory area 101, an address decoder 102, a pin array 103, a data input/output circuit 104, and a control circuit 105.

The memory area 101 may include a plurality of memory cells, and the plurality of memory cells may include one or both of volatile memory and nonvolatile memory. Examples of volatile memory include SRAM (Static RAM), DRAM (Dynamic RAM), and SDRAM (Synchronous DRAM); and examples of the nonvolatile memory include ROM (Read Only Memory), PROM (Programmable ROM), EEPROM (Electrically Erasable and Programmable ROM), EPROM (Electrically Programmable ROM), flash memory, PRAM (Phase change RAM), MRAM (Magnetic RAM), RRAM (Resistive RAM), and FRAM (Ferroelectric RAM). During a read operation of the semiconductor apparatus 100, data stored in the memory area 101 may be outputted. During a write operation of the semiconductor apparatus 100, data inputted from outside the semiconductor apparatus 100 may be stored in the memory area 101. The memory cells of the memory area 101 may be divided into a plurality of unit memory areas, for example, a plurality of memory banks. The plurality of memory banks may be divided into bank groups and controlled so as to be suitable for a read operation and write operation of the semiconductor apparatus 100.

The address decoder 102 may be coupled to the control circuit 105 and the memory area 101. The address decoder 102 may decode an address signal provided by the control circuit 105, and access the memory area 101 according to the decoding result. The address signal provided by the control circuit 105 may include a row address signal and a column address signal. The row address signal may include an address for selectively enabling a plurality of bank groups and an address for selectively enabling a plurality of memory banks. The address for selectively enabling the plurality of bank groups may be referred to as a bank group address, and the address for selectively enabling the plurality of memory banks may be referred to as a bank address.

The pin array 103 may include command and address integrated pins (CA) 103-1. Through the command and address integrated pins 103-1, a command CMD and an external address signal ADD may be sequentially inputted at predetermined timings.

The data input/output circuit 104 may be coupled to the memory area 101. The data input/output circuit 104 may exchange data with the outside or the inside of the semiconductor apparatus 100. The data input/output circuit 104 may include a data input buffer, a data output buffer, a data input/output pad, and the like.

The control circuit 105 may be coupled to the memory area 101, the address decoder 102, and the data input/output circuit 104. The control circuit 105 may perform control operations related to a read operation, write operation, and address processing operation of the semiconductor apparatus. The control circuit 105 may receive a command and external address from outside the semiconductor apparatus 100 through the command and address integrated pins CA. The control circuit 105 may include an address control circuit. The address control circuit may control the address signal such that the address signal is suitable for a read operation and write operation for each operation mode of the semiconductor apparatus 100. The address control circuit may latch the address signal at a preset timing, such that the address signal is suitable for the read operation and write operation for each operation mode of the semiconductor apparatus 100. The address control circuit may change the value of the address signal such that the address signal is suitable for the operation mode of the semiconductor apparatus 100.

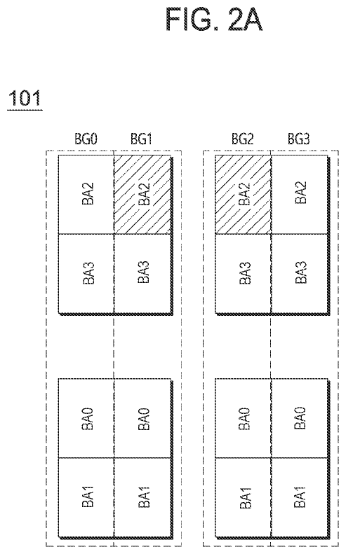

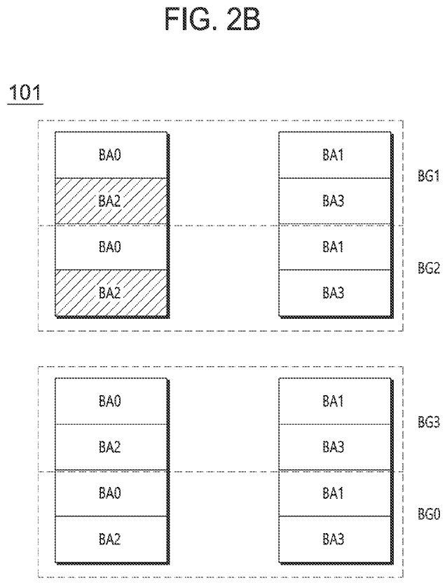

FIGS. 2A and 2B are diagrams illustrating an example of a bank group mode operation in accordance with an embodiment.

When the semiconductor apparatus 100 is designed, it may be designed to have a structure that reduces current consumption. There are various operation patterns IDD0, IDD2P, IDD3P, IDD2N, IDD3N, IDD4R, IDD4W, IDD5, and IDD6 for determining the current consumption characteristic of the semiconductor memory apparatus. The semiconductor apparatus 100 is designed to support a plurality of memory access modes. The plurality of memory access modes may include first to third memory access modes. The first memory access mode may be referred to as a bank group mode, the second memory access mode may be referred to as an 8-bank mode, and the third memory access mode may be referred to as a 16-bank mode. The bank group mode is an operation mode in which a plurality of memory banks are divided into unit groups and operated. The 8-bank mode is an operation mode in which a plurality of banks, e.g. 16 memory banks, are divided on a pair basis, such that the 16 memory banks are operated like 8 memory banks. The 16-bank mode is an operation mode in which a plurality of memory banks, e.g. 16 memory banks, are each selected and operated.

For example, the physical arrangement of the plurality of memory banks may be set to minimize the current consumption depending on the bank group mode of the semiconductor apparatus 100, and will be described with reference to FIGS. 2A and 2B.

FIG. 2A illustrates an example in which the physical arrangement of the memory banks is set to minimize the current consumption, when the semiconductor apparatus 100 is operated according to the IDD4R/IDD4W pattern based on the bank group mode. The IDD4R/IDD4W pattern may indicate consecutive read/write operations on two memory banks.

Referring to FIG. 2A, the plurality of memory banks of the memory area 101, e.g. 16 memory banks, may be divided into a plurality of bank groups BG0, BG1, BG2, and BG3 (hereafter, referred to BG0 to BG3) in a first direction of the drawing, e.g. a horizontal direction, and then controlled. The first direction is only set to the horizontal direction of the drawing for convenience of description, and is not limited thereto. Hereafter, BG0 represents a first bank group, BG1 represents a second bank group, BG2 represents a third bank group, and BG3 represents a fourth bank group. The plurality of bank groups BG0 to BG3 may be arranged in order of the first bank group BG0, the second bank group BG1, the third bank group BG2, and the fourth bank group BG3 from the left to right side of the drawing, for example.

The plurality of bank groups BG0 to BG3 may each include a plurality of memory banks BA0, BA1, BA2, and BA3 (hereafter, referred to as BA0 to BA3) arranged in a second direction of the drawing, e.g. a vertical direction. The second direction is only set to the vertical direction of the drawing for convenience of description, and is not limited thereto. Hereafter, BA0 represents a first memory bank, BA1 represents a second memory bank, BA2 represents a third memory bank, and BA3 represents a fourth memory bank. The plurality of memory banks BA0 to BA3 may be arranged in order of the third memory bank BA2, the fourth memory bank BA3, the first memory bank BA0, and the second memory bank BA1, for example.

When the semiconductor apparatus 100 is operated according to the IDD4R/IDD4W pattern based on the bank group mode, consecutive read/write operations may be performed on the third memory bank BA2 of the second bank group BG1 and the third memory bank BA2 of the third bank group BG2, as indicated in FIG. 2A by hatching, according to the operation standards of the semiconductor apparatus. That is, in order to reduce current consumption according to the IDD4R/IDD4W pattern, it is advantageous to perform consecutive read/write operations on memory banks which are physically the closest to each other and have the same number in order. Thus, the physical arrangement of the plurality of memory banks is set in a shape illustrated in FIG. 2A.

FIG. 2B illustrates another example in which the physical arrangement of the memory banks is set to minimize the current consumption, when the semiconductor apparatus 100 is operated according to the IDD4R/IDD4W pattern based on the bank group mode.

Referring to FIG. 2B, the plurality of memory banks of the memory area 101, e.g. 16 memory banks, may be divided into a plurality of bank groups BG0 to BG3 in the second direction of the drawing, e.g. the vertical direction, and then controlled. The second direction is only set to the vertical direction of the drawing for convenience of description, and is not limited thereto. The plurality of bank groups BG0 to BG3 may be arranged in order of the second bank group BG1, the third bank group BG2, the fourth bank group BG3, and the first bank group BG0 from the top to the bottom of the drawing, for example.

The plurality of bank groups BG0 to BG3 may each include a plurality of memory banks BA0 to BA3 arranged in the first and second directions of the drawing, i.e. the horizontal and the vertical directions. According to the arrangement of the plurality of memory banks BA0 to BA3, the first and second memory banks BA0 and BA1 may be arranged in the horizontal direction, and the third and fourth memory banks BA2 and BA3 may be arranged under the first and second memory banks BA0 and BA1, respectively.

When the semiconductor apparatus 100 is operated according to the IDD4R/IDD4W pattern based on the bank group mode, consecutive read/write operations may be performed on the third memory bank BA2 of the second bank group BG1 and the third memory bank BA2 of the third bank group BG2, as indicated in FIG. 2B by hatching, according to the operation standards of the semiconductor apparatus. That is, in order to reduce current consumption according to the IDD4R/IDD4W pattern, it is advantageous to perform consecutive read/write operations on memory banks which are physically the closest to each other and have the same number in order. Thus, the physical arrangement of the plurality of memory banks is set in a shape illustrated in FIG. 2B.

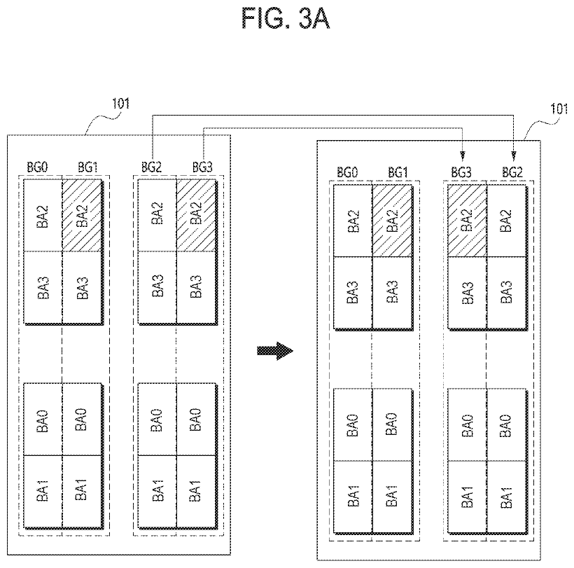

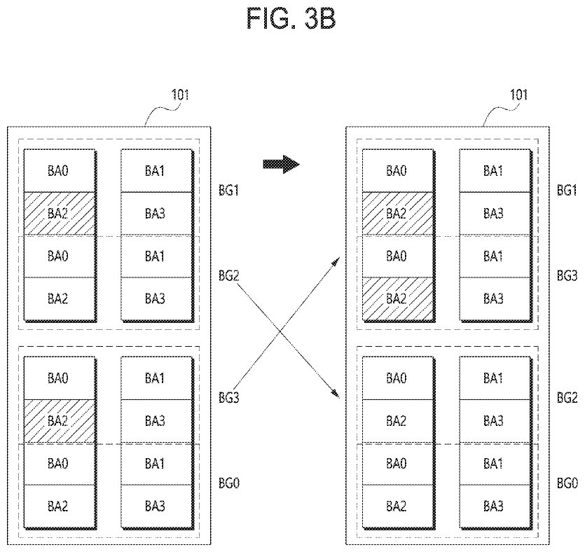

FIGS. 3A and 3B are diagrams illustrating an example of an 8-bank group mode operation in accordance with an embodiment.

Referring to the left side of FIG. 3A, when the semiconductor apparatus 100 including the memory area 101 having the physical arrangement illustrated in FIG. 2A is operated according to the IDD4R/IDD4W pattern based on the 8-bank mode, a memory bank which is selected according to the operation standards of the semiconductor apparatus is different from a memory bank selected in the above-described bank group mode. During the 8-bank mode operation, the third memory bank BA2 of the second bank group BG1 and the third memory bank BA2 of the fourth bank group BG3 may be operated like one memory bank. In the case of the IDD4R/IDD4W pattern based on the bank group mode, consecutive read/write operations are performed on the third memory bank BA2 of the second bank group BG1 and the third memory bank BA2 of the third bank group BG2. However, when the semiconductor apparatus 100 is operated according to the IDD4R/IDD4W pattern based on the 8-bank mode, consecutive read/write operations are performed on the third memory bank BA2 of the second bank group BG1 and the third memory bank BA2 of the fourth bank group BG3. As a result, in the 8-bank mode, the physical distance between the selected memory banks is increased more than in the bank group mode. Thus, the current consumption is increased while signal line loading is increased.

Therefore, in the present embodiment, the physical arrangement of the memory banks of the memory area 101 is not changed as illustrated in the right side of FIG. 3A, and even in the 8-bank mode, memory banks which are the closest to each other and have the same number in order may be selected through address control in the same manner as the bank group mode. That is, the third bank group BG2 and the fourth bank group BG3 may be recognized as the third bank group BG2 and the fourth bank group BG3, respectively, through address control. Hereafter, the operation of allowing bank groups to be differently recognized through address control will be referred to as an address mapping change operation.

Referring to the left side of FIG. 3B, when the semiconductor apparatus 100 including the memory area 101 having the physical arrangement illustrated in FIG. 2B is operated according to the IDD4R/IDD4W pattern based on the 8-bank mode, a memory bank which is selected according to the operation standards of the semiconductor apparatus is different from a memory bank selected in the above-described bank group mode. In the case of the IDD4R/IDD4W pattern based on the bank group mode, consecutive read/write operations are performed on the third memory bank BA2 of the second bank group BG1 and the third memory bank BA2 of the fourth bank group BG3. However, when the semiconductor apparatus 100 is operated according to the IDD4R/IDD4W pattern based on the 8-bank mode, consecutive read/write operations are performed on the third memory bank BA2 of the second bank group BG1 and the third memory bank BA2 of the fourth bank group BG3. As a result, in the 8-bank mode, the physical distance between the selected memory banks is increased more than in the bank group mode. Thus, the current consumption is increased while signal line loading is increased.

Therefore, in the present embodiment, the physical arrangement of the memory banks of the memory area 101 is not changed as illustrated in the right side of FIG. 3B, and even in the 8-bank mode, memory banks which are the closest to each other and have the same number in order may be selected through address control in the same manner as the bank group mode. That is, the third bank group BG2 and the fourth bank group BG3 may be recognized as the third bank group BG2 and the fourth bank group BG3, respectively, through the address control.

As a result, the semiconductor apparatus in accordance with the present embodiment may maintain the physical positions of the memory banks which are arranged to reduce the current consumption in the bank group mode. Simultaneously, even in the 8-bank mode, the semiconductor apparatus may select the memory banks, which are the closest to each other and have the same number in order, in the same manner as the bank group mode, thereby reducing the current consumption.

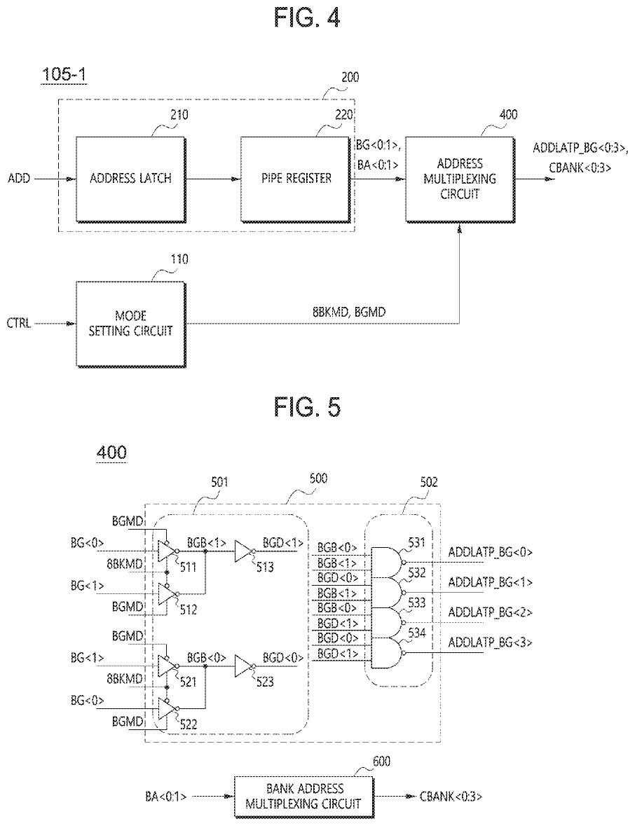

Hereafter, a circuit configuration for the address mapping change operation in accordance with the present embodiment will be described with reference to FIGS. 4 and 5.

FIG. 4 is a diagram illustrating a configuration of an address control circuit 105-1 in accordance with an embodiment.

Referring to FIG. 4, the address control circuit 105-1 may include a mode setting circuit 110, an address timing control circuit 200, and an address multiplexing circuit 400.

The mode setting circuit 110 may generate an access mode signal based on a preset memory access mode, e.g. a first access mode signal and a second access mode signal. The first access mode signal may be referred to as a bank group mode signal BGMD, and the second access mode signal may be referred to as an 8-bank mode signal 8BKMD. The 8-bank mode signal 8BKMD may be generated at a high level when the memory access mode of the semiconductor apparatus 100 is set to the 8-bank mode, and generated at a low level when the memory access mode is not set to the 8-bank mode. The bank group mode signal BGMD may be generated at a high level when the memory access mode of the semiconductor apparatus 100 is set to the bank group mode, and generated at a low level when the memory access mode is not set to the bank group mode.

The mode setting circuit 110 may generate the 8-bank mode signal 8BKMD and the bank group mode signal BGMD according to a control signal CTRL. The mode setting circuit 110 may include one or more of a mode register set and a fuse set. When the mode setting circuit 110 is configured as a mode register set, a mode register write command may be used as the control signal CTRL. When the mode setting circuit 110 is configured as a fuse set, a signal for fuse set program, e.g. a test mode signal, may be used as the control signal CTRL.

The address timing control circuit 200 may latch address signals ADD inputted from the outside of the semiconductor apparatus 100, sequentially store the latched signals at predetermined timings, and output the stored signals as a bank group address BG<0:1> and a bank address BA<0:1>. The address timing control circuit 200 may include an address latch 210 and a pipe register 220.

The address latch 210 may latch the address signals ADD inputted from the outside of the semiconductor apparatus 100 and output the latched signals. Through the command and address integrated pins CA described with reference to FIG. 1, the command and the address signals ADD may be sequentially inputted. The address signals ADD may include address signals for bank group selection, bank selection, and column access.

The pipe register 220 may sequentially store the signals outputted from the address latch 210 at predetermined timings, and output the stored signals as the bank group address BG<0:1> and the bank address BA<0:1>. Although not illustrated, the pipe register 220 may also store and output addresses related to the column access of the semiconductor apparatus 100.

The address multiplexing circuit 400 may perform an address mapping change operation of changing the value of the bank group address BG<0:1> according to the access mode signals 8BKMD and BGMD. The address multiplexing circuit 400 may generate bank group select signals ADDLATP_BG<0:3> by controlling the bank group address BG<0:1> in different manners depending on the 8-bank mode signal 8BKMD and the bank group mode signal BGMD. Although the value of the bank group address BG<0:1> is changed as the memory access mode of the semiconductor apparatus 100 is changed, the address multiplexing circuit 400 may generate the bank group select signals ADDLATP_BG<0:3> as the same values. When it is assumed that the bank group address BG<0:1>, which is inputted when the memory access mode of the semiconductor apparatus 100 is set to the bank group mode, has a value of ‘01’, the bank group address BG<0:1> may be inputted as a value of ‘10’ in the 8-bank mode, which is different from that in the bank group mode.

When the bank group mode signal BGMD has a high level or the memory access mode of the semiconductor apparatus 100 is set to the bank group mode, the address multiplexing circuit 400 may generate the bank group select signals ADDLATP_BG<0:3> having a second value (e.g. ‘Z’) according to the bank group address BG<0:1> having a first value (e.g. ‘X’). When the 8-bank mode signal 8BKMD has a high level or the memory access mode of the semiconductor apparatus 100 is set to the 8-bank mode, the address multiplexing circuit 400 may generate the bank group select signals ADDLATP_BG<0:3> having the second value (e.g. ‘Z’), even though the bank group address BG<0:1> having a third value (e.g. ‘Y’) different from the first value (e.g. ‘X’) is inputted. The address multiplexing circuit 400 may generate bank select signals CBANK<0:3> according to the bank address BA<0:1>.

FIG. 5 is a diagram illustrating a configuration of the address multiplexing circuit 400 in accordance with an embodiment.

Referring to FIG. 5, the address multiplexing circuit 400 may include a bank group address multiplexing circuit 500 and a bank address multiplexing circuit 600.

The bank group address multiplexing circuit 500 may generate the bank group select signals ADDLATP_BG<0:3> according to the bank group address BG<0:1>, the 8-bank mode signal 8BKMD, and the bank group mode signal BGMD.

The bank group address multiplexing circuit 500 may include an address multiplexer 501 and a decoding circuit 502. The address multiplexer 501 may generate pre-decoding signals BGB<1>, BGD<1>, BGB<0>, and BGD<0> by selectively combining the address bits of the bank group address BG<0:1> according to the 8-bank mode signal 8BKMD and the bank group mode signal BGMD. The address multiplexer 501 may include a plurality of logic gates 511 to 513 and 521 to 523. A first logic gate 511 may output a signal, obtained by inverting the bank group address BG<0>, as a first pre-decoding signal BGB<1> according to the 8-bank mode signal 8BKMD and the bank group mode signal BGMD. When the memory access mode of the semiconductor apparatus 100 is the 8-bank mode, the 8-bank mode signal 8BKMD may be set to a high level, and the bank group mode signal BGMD may be set to a low level. When the memory access mode of the semiconductor apparatus 100 is the bank group mode, the 8-bank mode signal 8BKMD may be set to a low level, and the bank group mode signal BGMD may be set to a high level. When the memory access mode of the semiconductor apparatus 100 is the 8-bank mode, the first logic gate 511 may output a signal, obtained by inverting the bank group address BG<0>, as the first pre-decoding signal BGB<1>. When the memory access mode of the semiconductor apparatus 100 is the bank group mode, the first logic gate 511 may retain the level of an output terminal thereof as the initial level, regardless of the level of the bank group address BG<0>.

A second logic gate 512 may output a signal, obtained by inverting the bank group address BG<1>, as the first pre-decoding signal BGB<1> according to the 8-bank mode signal 8BKMD and the bank group mode signal BGMD. When the memory access mode of the semiconductor apparatus 100 is the bank group mode, the second logic gate 512 may output a signal, obtained by inverting the bank group address BG<1>, as the first pre-decoding signal BGB<1>. When the memory access mode of the semiconductor apparatus 100 is the 8-bank mode, the second logic gate 512 may retain the level of an output terminal thereof as the initial level, regardless of the level of the bank group address BG<1>. A third logic gate 513 may output a signal, obtained by inverting the first pre-decoding signal BGB<1>, as a second pre-decoding signal BGD<1>.

When the memory access mode of the semiconductor apparatus 100 is the 8-bank mode, a fourth logic gate 521 may output a signal, obtained by inverting the bank group address BG<1>, as a third pre-decoding signal BGB<0>. When the memory access mode of the semiconductor apparatus 100 is the bank group mode, the fourth logic gate 521 may retain the level of an output terminal thereof as the initial level, regardless of the level of the bank group address BG<1>.

When the memory access mode of the semiconductor apparatus 100 is the bank group mode, a fifth logic gate 522 may output a signal, obtained by inverting the bank group address BG<0>, as the third pre-decoding signal BGB<0>. When the memory access mode of the semiconductor apparatus 100 is the 8-bank mode, the fifth logic gate 522 may retain the level of an output terminal thereof as the initial level, regardless of the level of the bank group address BG<0>. A sixth logic gate 523 may output a signal, obtained by inverting the third pre-decoding signal BGB<0>, as a fourth pre-decoding signal BGD<0>.

The decoding circuit 502 may output signals, obtained by decoding the first pre-decoding signal BGB<1>, the second pre-decoding signal BGD<1>, the third pre-decoding signal BGB<0>, and the fourth pre-decoding signal BGD<0>, as the bank group select signals ADDLATP_BG<0:3>. The decoding circuit 502 may include a plurality of logic gates 531 to 534.

A first logic gate 531 may output a signal, obtained by performing a NAND operation on the third pre-decoding signal BGB<0> and the first pre-decoding signal BGB<1>, as a first bank group select signal ADDLATP_BG<0>. According to the first bank group select signal ADDLATP_BG<0>, the first bank group BG0 may be selected among the plurality of bank groups BG0 to BG3.

A second logic gate 532 may output a signal, obtained by performing a NAND operation on the fourth pre-decoding signal BGD<0> and the first pre-decoding signal BGB<1>, as a second bank group select signal ADDLATP_BG<1>. According to the second bank group select signal ADDLATP_BG<1>, the second bank group BG1 may be selected among the plurality of bank groups BG0 to BG3.

A third logic gate 533 may output a signal, obtained by performing a NAND operation on the third pre-decoding signal BGB<0> and the second pre-decoding signal BGD<1>, as a third bank group select signal ADDLATP_BG<2>. According to the third bank group select signal ADDLATP_BG<2>, the third bank group BG2 may be selected among the plurality of bank groups BG0 to BG3.

A fourth logic gate 534 may output a signal, obtained by performing a NAND operation on the fourth pre-decoding signal BGD<0> and the second pre-decoding signal BGD<1>, as a fourth bank group select signal ADDLATP_BG<3>. According to the fourth bank group select signal ADDLATP_BG<3>, the fourth bank group BG3 may be selected among the plurality of bank groups BG0 to BG3.

As described above, the bank group address multiplexing circuit 500 may combine and decode the bank group address BG<0:1> by changing the order of the bank group address BG<0:1> in the bank group mode and the 8-bank mode. Therefore, although the value of the bank group address BG<0:1> inputted in the bank group mode is different from the value of the bank group address BG<0:1> inputted in the 8-bank mode, the bank group select signals ADDLATP_BG<0:3> having the same value may be generated.

The bank address multiplexing circuit 600 may output a signal, obtained by decoding the bank address BA<0:1>, as the bank select signals CBANK<0:3>. According to the bank select signals CBANK<0:3>, one memory bank may be selected among the plurality of memory banks BA0 to BA3 of each of the plurality of bank groups BG0 to BG3.

While various embodiments have been described above, it will be understood by those skilled in the art that these embodiments represent examples only. Accordingly, the address control circuit and the semiconductor apparatus, which are described herein, should not be limited based on the described embodiments.

What is claimed is:

1. An address control circuit comprising:
an address timing control circuit configured to latch address signals inputted from outside the address timing control circuit, sequentially store the latched signals at predetermined timings, and output the stored signals as a bank group address; and
an address multiplexing circuit configured to generate bank group select signals according to the bank group address,
wherein the address multiplexing circuit is configured to:
generate the bank group select signals having a second value according to the bank group address having a first value when a preset memory access mode is a first memory access mode, and
generate the bank group select signals having the second value according to the bank group address having a third value different from the first value when the preset memory access mode is a second memory access mode.

2. The address control circuit according to claim 1, further comprising a mode setting circuit configured to:
generate access mode signals for defining the preset memory access mode; and
provide the generated access mode signals to the address multiplexing circuit.

3. The address control circuit according to claim 2, wherein the mode setting circuit is configured to generate the access mode signals according to at least one of a mode register write command and a test mode signal for a fuse set program.

4. The address control circuit according to claim 1, wherein the address timing control circuit comprises:
an address latch configured to latch address signals inputted from outside the address timing control circuit, and output the latched signals; and
a pipe register configured to sequentially store the signals outputted from the address latch at predetermined timings, and output the stored signals as the bank group address.

5. The address control circuit according to claim 1, wherein the address multiplexing circuit comprises:
an address multiplexer configured to generate pre-decoding signals by selectively combining address bits of the bank group address according to access mode signals for setting the memory access mode; and
a decoding circuit configured to output signals, obtained by decoding the pre-decoded signals, as the bank group select signals.

6. The address control circuit according to claim 1, wherein the address multiplexing circuit comprises:
an address multiplexer configured to:
generate some pre-decoding signals according to a first address bit of the bank group address and generate the others of the pre-decoding signals according to a second address bit of the bank group address, when the memory access mode is the first memory access mode; and
generate some of the pre-decoding signals according to the second address bit of the bank group address and generate the others of the pre-decoding signals according to the first address bit of the bank group address, when the memory access mode is the second memory access mode; and
a decoding circuit configured to output signals, obtained by decoding the pre-decoding signals, as the bank group select signals.

7. A semiconductor apparatus comprising:
a memory area comprising a plurality of memory banks divided into a plurality of bank groups; and
an address control circuit configured to generate bank group select signals according to a bank group address,
wherein the address control circuit is configured to:
generate the bank group select signals having a second value according to the bank group address having a first value when a preset memory access mode is a first memory access mode, and generate the bank group select signals having the second value according to the bank group address having a third value different from the first value when the preset memory access mode is a second memory access mode, and
selectively operate the plurality of bank groups when the memory access mode is the first memory access mode, and pair the plurality of memory banks and selectively operate the paired memory banks when the memory access mode is the second memory access mode.

8. The semiconductor apparatus according to claim 7, wherein the address control circuit comprises:
an address multiplexer configured to generate pre-decoding signals by selectively combining address bits of the bank group address according to access mode signals for setting the memory access mode; and
is a decoding circuit configured to output signals, obtained by decoding the pre-decoding signals, as the bank group select signals.

9. The semiconductor apparatus according to claim 7, wherein the address control circuit comprises:
an address multiplexer configured to:
generate some pre-decoding signals according to a first address bit of the bank group address and generate the others of the pre-decoding signals according to a second address bit of the bank group address, when the memory access mode is the first memory access mode, and
generate some of the pre-decoding signals according to the second address bit of the bank group address and generate the others of the pre-decoding signals according to the first address bit of the bank group address, when the memory access mode is the second memory access mode; and
a decoding circuit configured to output signals, obtained by decoding the pre-decoding signals, as the bank group select signals.

10. A semiconductor apparatus comprising:
a memory area comprising a plurality of memory banks divided into a plurality of bank groups; and
an address control circuit configured to generate bank group select signals for selecting any one bank group among the plurality of bank groups according to a bank group address,
wherein the address control circuit is configured to change values of the bank group select signals in order to match two bank groups selected in a first memory access mode with two bank groups selected in a second memory access mode, during consecutive read operations on two different memory banks among the plurality of memory banks.

11. The semiconductor apparatus according to claim 10, wherein the semiconductor apparatus is configured to selectively operate the plurality of bank groups when the first memory access mode is set, and pair the plurality of memory banks and selectively operate the paired memory banks when the second memory access mode is set.

12. The semiconductor apparatus according to claim 10, wherein the address control circuit is configured to change the values of the bank group select signals in order to match two bank groups selected in a first memory access mode with two bank groups selected in a second memory access mode, during consecutive write operations on two different memory banks among the plurality of memory banks.

13. The semiconductor apparatus according to claim 10, wherein the two bank groups selected in the first memory access mode are located at positions which are physically the closest to each other.

14. The semiconductor apparatus according to claim 10, wherein the address control circuit is configured to:
generate the bank group select signals having a second value according to the bank group address having a first value when the first memory access mode is set, and
generate the bank group select signals having the second value according to the bank group address having a third value when the second memory access mode is set.

15. The semiconductor apparatus according to claim 10, wherein the address control circuit comprises:
an address multiplexer configured to generate pre-decoding signals by selectively combining address bits of the bank group address according to access mode signals for setting the first and second memory access modes; and
a decoding circuit configured to output signals, obtained by decoding the pre-decoding signals, as the bank group select signals.

16. The semiconductor apparatus according to claim 10, wherein the address control circuit comprises:
an address multiplexer configured to:
generate some pre-decoding signals according to a first address bit of the bank group address and generate the others of the pre-decoding signals according to a second address bit of the bank group address, when the memory access mode is the first memory access mode, and
generate some of the pre-decoding signals according to the second address bit of the bank group address and generate the others of the pre-decoding signals according to the first address bit of the bank group address, when the memory access mode is the second memory access mode; and
a decoding circuit configured to output signals, obtained by decoding the pre-decoding signals, as the bank group select signals.
